(19) United States
(12) Patent Application Publication
(10) Pub. No.: US 2016/0181093 A1
(43) Pub. Date: Jun. 23, 2016

(54) III-N EPITAXY ON MULTILAYER BUFFER WITH PROTECTIVE TOP LAYER

(71) Applicants: Rytis Dargis, Fremont, CA (US); Andrew Clark, Los Altos, CA (US); Erdem Arkun, San Carlos, CA (US); Nam Pham, Palo Alto, CA (US)

(72) Inventors: Rytis Dargis, Fremont, CA (US); Andrew Clark, Los Altos, CA (US); Erdem Arkun, San Carlos, CA (US); Nam Pham, Palo Alto, CA (US)

(21) Appl. No.: 14/576,500

(22) Filed: Dec. 19, 2014

(51) Int. Cl. H01L 21/02

(52) U.S. Cl. CPC H01L 21/02488; H01L 21/02381; H01L 21/0254

(57) ABSTRACT

A method of growing III-N material on a silicon substrate including the steps of epitaxially growing a buffer layer of REO material on a silicon substrate, epitaxially growing a layer of REN material on the surface of the buffer, and epitaxially growing a thin protective layer of REO on the surface of the REN material layer. The substrate and structure can then be conveniently transferred to another growth machine in which are performed the steps of transforming or modifying in-situ the REO protective layer to a REN layer with a nitrogen treatment and epitaxially growing a layer of III-N material on the modified protective layer.

### FIELD OF THE INVENTION

This invention relates in general to the growth of III-N material on a Si substrate including the formation of a buffer including a rare earth oxide layer and a rare earth nitride layer and more specifically to the growth of a protective layer on the rare earth nitride layer.

### BACKGROUND OF THE INVENTION

GaN or other III-M semiconductor based electronics and optoelectronics need low cost and scalable substrates, such as silicon wafers or silicon based wafers. It is known that growing III-N semiconductor material layers, such as GaN, on a silicon substrate is difficult due in large part to the large crystal lattice mismatch (−16.9%) and the thermal mismatch (56%) between silicon and GaN. Thus, some type of buffer layer or layers is generally formed on the silicon substrate and the III-N material is grown on the buffer layer or layers. Generally, the prior art buffer layers are either complicated and expensive to form or do no adequately reduce the strain in the III-N due to crystal lattice mismatch.

It would be highly advantageous, therefore, to remedy the foregoing and other deficiencies inherent in the prior art.

Accordingly, it is an object of the present invention to provide new and improved methods for the growth of single crystal GaN material on a Si substrate.

It is another object of the present invention to provide new and improved methods for the growth of single crystal GaN material on a Si substrate using an improved buffer.

### SUMMARY OF THE INVENTION

Briefly, the desired objects and aspects of the instant invention are realized in accordance with a method of growing III-N material on a silicon substrate including the steps of epitaxially growing a buffer layer of REO material on a silicon substrate, epitaxially growing a layer of REN material on the surface of the buffer, and epitaxially growing a thin protective layer of REO on the surface of the REN material layer. The substrate and structure can then be conveniently transferred to another growth machine in which are performed the steps of transforming or modifying in-situ the REO protective layer to a REN layer with a nitrogen treatment and epitaxially growing a layer of III-N material on the modified protective layer.

The desired objects and aspects of the instant invention are further realized in a more specific method of growing III-N material on a silicon substrate including the steps of providing a single crystal silicon substrate; in a rare earth growth machine, growing a structure on the substrate including epitaxially growing a single crystal buffer layer on the single crystal silicon substrate, the single crystal buffer layer including rare earth oxide with a lattice spacing adjacent the single crystal silicon substrate substantially similar to a lattice spacing of silicon, epitaxially growing a layer of single crystal REN material on the surface of the buffer, the REN material having a lattice spacing adjacent the upper surface substantially similar to a lattice spacing of III-N, and epitaxially growing a thin protective layer of REO on the surface of the REN material layer. The method further includes the steps of transferring the structure on the substrate from the rare earth growth machine to a III-N growth machine and in the III-N growth machine transforming or modifying in-situ the REO protective layer to a REN layer with a nitrogen treatment and epitaxially growing a layer of single crystal III-N material on the modified protective layer.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a chart illustrating the crystal lattice relationship between GaN (a III-N material) and various rare earth oxides and nitrides;

FIG. 2 is a simplified layer diagram illustrating initial steps in a method of growing a buffer on a Si substrate, in accordance with the present invention;

FIG. 3 illustrates the simplified layer diagram of FIG. 2 including intermediate steps in the method; and

FIG. 4 illustrates the simplified layer diagram of FIG. 3 after the intermediate steps and including additional steps of growing III-N material on the completed buffer.

### DETAILED DESCRIPTION OF THE DRAWINGS

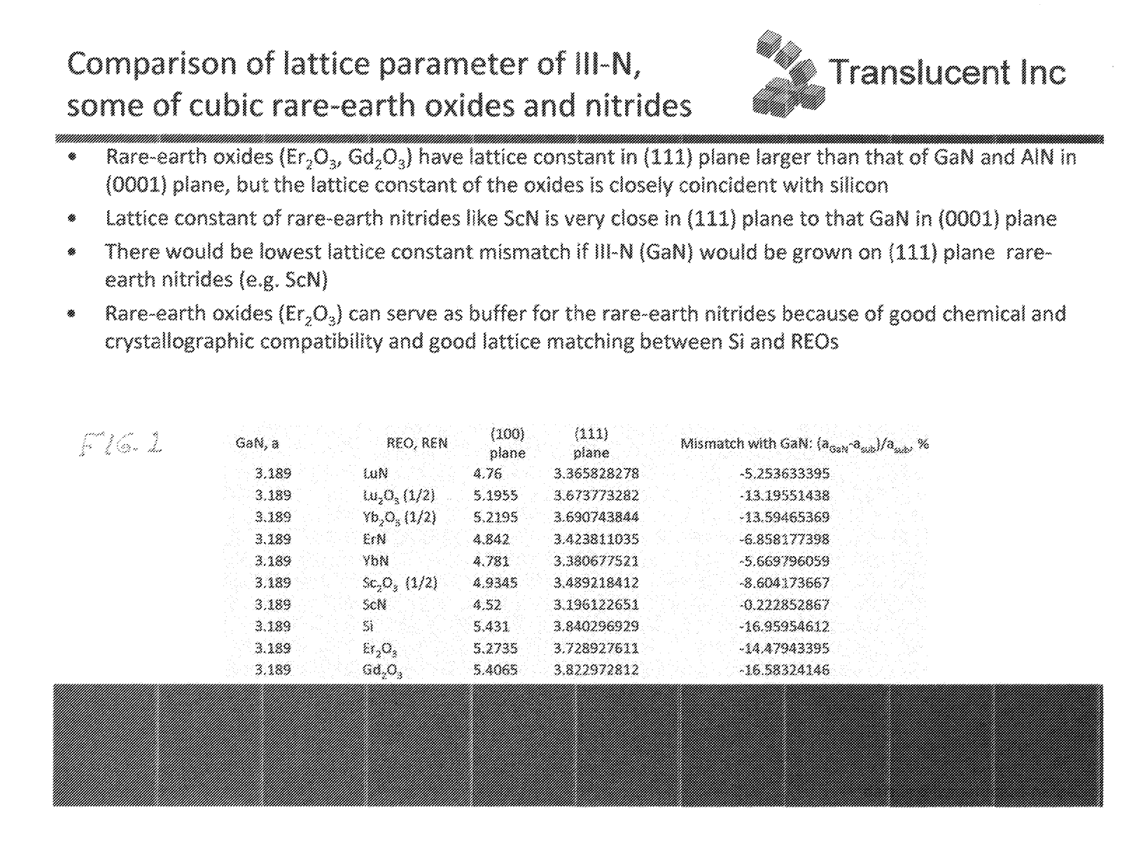

Because growing III-N semiconductor material layers, such as GaN, InN, or AlN, on a silicon substrate is difficult due in large part to the large crystal lattice mismatch and the thermal mismatch, some type of buffer layer or layers is generally formed on the silicon substrate. As can be determined by referring to the chart in FIG. 1, rare-earth oxides (e.g. Er₂O₃, Gd₂O₃) have lattice constants in the (111) plane larger than that of GaN and AlN in the (0001) plane, but the lattice constants of the rare-earth oxides are closely coincident with silicon. However, the lattice constant of rare-earth nitrides, like ScN, is very close in the (111) plane to that of GaN in the (0001) plane. Thus, there is a low lattice constant mismatch if GaN in the (0001) plane can be grown on the (111) plane of a rare-earth nitride (e.g. ScN). In such an arrangement, rare-earth oxides (e.g. Er₂O₃) can serve as a buffer on the silicon for the rare-earth nitrides because of good chemical and crystallographic compatibility and good lattice matching between Si and the REOs.

A major problem that arises in the above process is that rare-earth nitrides are not stable in atmosphere and quickly transform into rare-earth hydroxide which is unsuitable for growth of III-N material. For the transfer of templates with an upper exposed layer of rare-earth nitride from the machine in which they are grown to a III-N growth machine, the templates must remain in a vacuum, which is complicated from a technological point of view and especially if GaN is grown by the MOCVD process. Another possibility is to cap the rare-earth nitride layer in-vacuo with a layer (such as SiO₂) that could be removed just before loading the templates into the III-N growth machine. However, such a process would lead to exposure of the rare-earth nitride layer to additional treatment, such as ionic or chemical. A further drawback is that the process requires additional technological steps adding complexity and cost.

In the present invention the problem is substantially solved by growing a cap protection layer on the rare-earth nitride layer that can protect the rare-earth nitride layer from the atmosphere during transfer to a III-N growth machine. Referring to FIG. 2, a simplified layer diagram illustrates initial steps in a method of growing a buffer on a Si substrate 10, in accordance with the present invention. It will be understood that substrate 10 is or may be a standard well known single crystal wafer or portion thereof generally known and used in the semiconductor industry. Also, the term “substrate” simply refers to a supporting structure and may be a layer of silicon-containing material positioned on a base layer of other material such as an oxide or the like. All such silicon or silicon containing materials are hereinafter referred to as “single crystal silicon” for convenience and the substrate as a “single crystal silicon substrate”.

In the present invention, as illustrated in FIG. 2, a buffer layer 12 of single crystal rare-earth oxide (REO) is epitaxially grown on single crustal silicon substrate 10. Layer 12 preferably includes a rare-earth oxide with a crystal lattice spacing close to the spacing of silicon. Various rare earth oxides have a crystal lattice spacing that can be substantially matched to silicon with very little strain. For example, Gd₂O₃ has a crystal lattice spacing (a) of 10.81 Å, Er₂O₃ has a crystal lattice spacing (a) of 10.55 Å, Nd₂O₃ has a crystal lattice spacing (a) of 11.08 Å, and silicon has a double spacing (2a) of 10.86 Å. Also, two or more rare earth materials can be mixed in a layer or layers to bring the crystal spacing to a desired level and produce tensile or compressive strain as desired to offset strain in later deposited layers. Thus, REOa˜Si2a herein is defined as a “substantial crystallographic match”. Further, the crystal lattice spacing of the REO layer or layers can be varied by varying the composition of the constituents.

In this example Gd₂O₃ is the preferred rare earth oxide and provides a substantial crystallographic match with silicon substrate 10 while retaining the (111) orientation. Single crystal gadolinium oxide (Gd₂O₃) is epitaxially grown on silicon substrate 10 preferably by MBE but could instead be grown by MOCVD or any other technique, depending upon the specific application and additional growth techniques utilized.

A second buffer layer 14 of rare-earth nitride (REN) is epitaxially grown on the surface of buffer layer 12 preferably by MBE but could instead be grown by MOCVD or any other technique. REN buffer layer 14, because it is grown epitaxially on REO layer 12, has a (111) crystal orientation, the same as REO buffer layer 12 but has a crystal spacing that more closely matches the spacing of GaN. In this specific example, REN buffer layer 14 includes single crystal scandium nitride (ScN) with a smaller crystal spacing than the crystal spacing of the single crystal gadolinium oxide (Gd₂O₃), which reduces any stress in subsequent layers so that a substantially deformation free layer of III-N material can be grown on the upper surface.

Without removing the structure from the rare earth growth chamber (in-situ), a thin protective layer 16 of rare-earth oxide is epitaxially grown on the surface of REN layer 14. In this preferred embodiment, REO protective layer 16 is grown to a thickness in a range of 5 nm to 20 nm. As will be apparent from the remainder of the process, the thinner Reo protective layer 16 can be grown the simpler the remaining steps become. While the rare-earth material in protective layer 16 may be any convenient rare-earth material, in the preferred embodiment the rare-earth metal in protective layer 16 is the same rare-earth metal as included in REN buffer layer 14, for reasons that will become apparent presently.

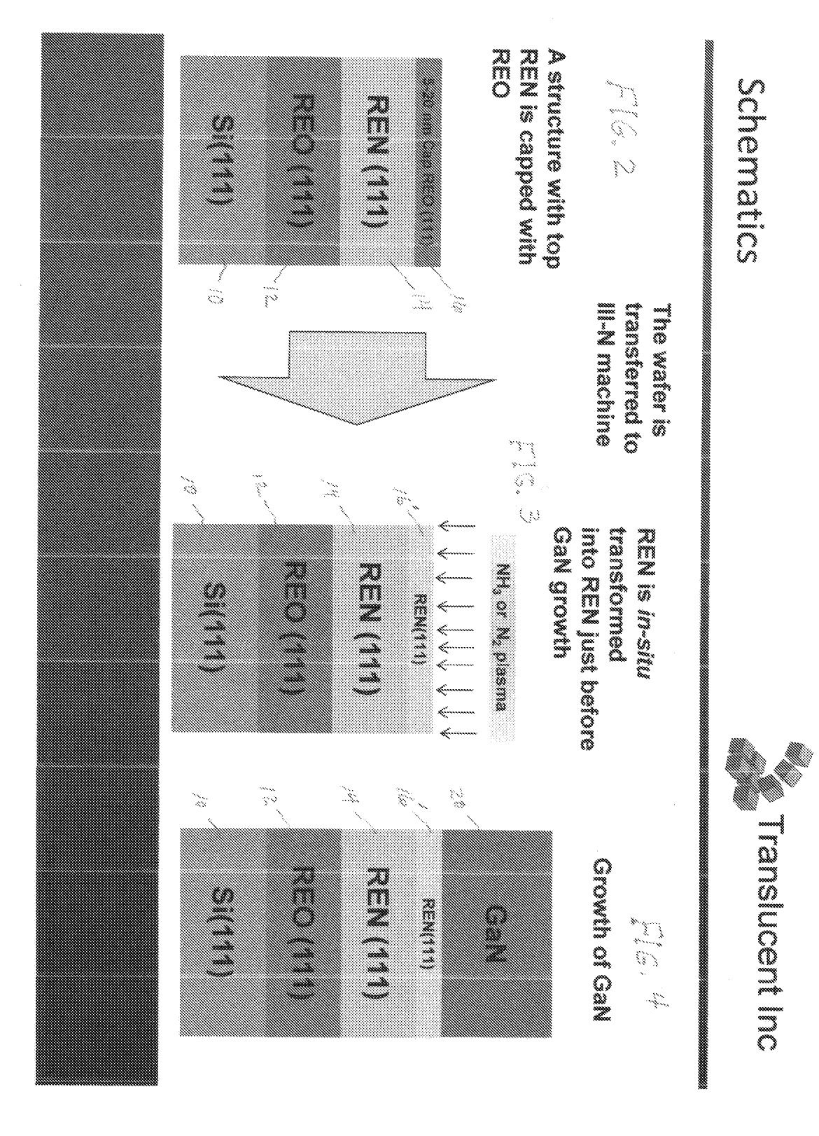

Turning to FIG. 3, the structure illustrated in FIG. 2 is transferred to a machine for epitaxially depositing a III-N material. Because REO protective layer 16 protects REN layer 14 from the atmosphere during transfer, no special care is required. Once the structure is in place in the III-N growth machine, REO protective layer 16 is in-situ modified by a nitrogen treatment, for example using or applying either N2, NH3, or nitrogen plasma, into rare-earth nitride layer 16′ which, in the preferred embodiment has the same crystalline structure as REN layer 14 underneath REO protective layer 16. Thus, in this preferred embodiment, layer 16′ simply becomes a continuation of layer 14.

The III-N growth machine is then used to epitaxially grow in-situ a layer or layers of III-N material, designated 20, on layer 16′. III-N layer 20 can be grown by MOCVD, MBE, or any other desired process. Because III-N layer 20 and REN layer 14/16′ are closely matched, layer 20 can be grown sufficiently thick and with few to no defects so that formation of semiconductor based electronics and/or optoelectronics can be formed therein.

Thus, a new and novel method of growing III-N material on a single crystal silicon substrate has been disclosed. The new method includes a multi-layer rare earth buffer that is substantially crystal lattice matched to a single crystal silicon substrate at the lower surface and to the III-N material at the upper surface. The III-N material match is enhanced by a thin modifiable protective layer of rare-earth oxide. The result is that because of the new and novel process of protecting REN during the processing steps, the upper layer of the buffer can be epitaxially grown REN which greatly improves the epitaxial growth of III-N material. The process of protecting the REN layer is very simple and does not add any complex steps outside of the normal in-situ operations. The new method provides the III-N material in a substantially stress and defect free form that is convenient for use in electronic and photonic devices and is easy to perform.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of growing III-N material on a silicon substrate comprising the steps of:
providing a single crystal silicon substrate;
epitaxially growing a single crystal buffer layer on the single crystal silicon substrate, the single crystal buffer layer including rare earth oxide with a lattice spacing adjacent the single crystal silicon substrate substantially similar to a lattice spacing of silicon;
epitaxially growing a layer of single crystal REN material on the surface of the buffer, the REN material having a lattice spacing adjacent the upper surface substantially similar to a lattice spacing of III-N;
epitaxially growing a thin protective layer of REO on the surface of the REN material layer;
transferring the substrate with the layer of single crystal REN material and thin protective layer of REO thereon from a REO growth machine to a III-N growth machine;
transforming or modifying in-situ in the III-N growth machine the REO protective layer to a REN layer with a nitrogen treatment; and
epitaxially growing a layer of single crystal III-N material on the modified protective layer.

2. (canceled)

3. The method as claimed in claim 1 wherein the REO protective layer includes the same rare-earth metal as the layer of REN material.

4. The method as claimed in claim 1 where, in the step of transforming or modifying in-situ the REO protective layer, the nitrogen treatment includes using or applying either N2, NH3, or nitrogen plasma.

5. The method as claimed in claim 1 wherein the step of epitaxially growing a single crystal buffer layer includes epitaxially growing a layer including one of Gd₂O₃, Er₂O₃, and Nd₂O₃.

6. The method as claimed in claim 5 wherein the step of epitaxially growing a single crystal buffer layer includes epitaxially growing a layer including Gd₂O₃.

7. The method as claimed in claim 1 wherein the step of epitaxially growing a thin protective layer of REO includes growing a layer with a thickness in a range of 5 nm to 20 nm.

8. The method as claimed in claim 1 wherein the step of epitaxially growing a layer of single crystal REN material includes epitaxially growing a layer of single crystal scandium nitride (ScN).

9. The method as claimed in claim 8 wherein the step of epitaxially growing a thin protective layer of REO includes epitaxially growing a layer including Sc₂O₃.

10. The method as claimed in claim 1 wherein the step of epitaxially growing the layer of single crystal III-N material includes epitaxially growing one of single crystal GaN, InN, or AlN.

11. A method of growing III-N material on a silicon substrate comprising the steps of:
providing a single crystal silicon substrate;
epitaxially growing a single crystal buffer layer on the single crystal silicon substrate, the single crystal buffer layer including one of Gd₂O₃, Er₂O₃, and Nd₂O₃;
epitaxially growing a layer of single crystal scandium nitride material on the surface of the single crystal buffer layer;
epitaxially growing a thin protective layer of scandium oxide material on the surface of the layer of single crystal scandium nitride material;
transferring the substrate with the layer of single crystal scandium nitride material and thin protective layer of scandium oxide material thereon from a REO growth machine to a III-N growth machine;
transforming or modifying in-situ in the III-N growth machine the layer of single crystal scandium oxide material to a single crystal scandium nitride material layer with a nitrogen treatment; and
epitaxially growing a layer of one of single crystal GaN, InN, or AlN material on the layer of single crystal scandium nitride material.

12. The method as claimed in claim 11 wherein the step of epitaxially growing a thin protective layer of scandium oxide material includes growing a layer with a thickness in a range of 5 nm to 20 nm.

13. (canceled)

14. A method of growing III-N material on a silicon substrate comprising the steps of:
providing a single crystal silicon substrate;
in a rare earth growth machine, growing a structure on the substrate including the step of:
epitaxially growing a single crystal buffer layer on the single crystal silicon substrate, the single crystal buffer layer including rare earth oxide with a lattice spacing adjacent the single crystal silicon substrate substantially similar to a lattice spacing of silicon;
epitaxially growing a layer of single crystal REN material on the surface of the buffer, the REN material having a lattice spacing adjacent the upper surface substantially similar to a lattice spacing of III-N; and
epitaxially growing a thin protective layer of REO on the surface of the REN material layer;
transferring the structure on the substrate from the rare earth growth machine to a III-N growth machine; and
in the III-N growth machine:
transforming or modifying in-situ the REO protective layer to a REN layer with a nitrogen treatment; and
epitaxially growing a layer of single crystal III-N material on the modified protective layer.

15. The method as claimed in claim 14 wherein the rare earth growth machine includes one of an MOCVD or MBE machine.

16. The method as claimed in claim 14 wherein the III-N growth machine includes one of an MOCVD or MBE machine.

17. The method as claimed in claim 14 wherein the step of epitaxially growing a thin protective layer of REO material includes growing a layer with a thickness in a range of 5 nm to 20 nm.

18. The method as claimed in claim 14 where, in the step of transforming or modifying in-situ the REO protective layer, the nitrogen treatment includes using or applying either N2, NH3, or nitrogen plasma.
